(19) United States
(12) Patent Application Publication
(10) Pub. No.: US 2011/0088780 A1
(43) Pub. Date: Apr. 21, 2011

(54) Solar Component for Solar Thermal Installations, Solar Thermal Installation, Method for Operating a Solar Thermal Installation, and Parts of a Solar Component for Solar Thermal Installations

(76) Inventor: Ludger Hambrock, Borken (DE)

(21) Appl. No.: 12/899,694

(22) Filed: Oct. 7, 2010

(30) Foreign Application Priority Data
Oct. 7, 2009 (DE) 10 2009 045 466.7
Jul. 13, 2010 (DE) 10 2010 036 383.9

(51) Int. Cl. H01L 31/00; F24J 2/24; F24J 2/46

(52) U.S. Cl. 136/259; 126/651; 126/704

(57) ABSTRACT

A solar component for solar thermal installations has an absorber element and at least one tube for a fluid thermal medium, coupled thermally directly or indirectly to the absorber element. At least one solid insulation of foam glass or plastic, in particular a cured plastic foam made of polyurethane or polyisocyanurate, is provided. The solid insulation, when mounted as intended, fixes the at least one tube relative to the absorber element.

### TECHNICAL FIELD OF THE INVENTION

The invention relates to a solar component for solar thermal installations, a solar thermal installation, a method for operating a solar thermal installation and specific parts of a solar component for solar thermal installations.

### BACKGROUND OF THE INVENTION

Solar thermal installations have been known for a long time. They are based on the basic principle of circulating a fluid medium in a heat transfer medium circuit and letting this be heated by the sun, wherein the heated medium then passes through a heat exchanger in which it delivers the absorbed thermal energy to another medium, in particular for the heating of heating water, fresh water or industrial water.

The known installations usually use so-called flat collectors which are attached to a flat side of a roof which receives the most solar irradiation averaged over the year.

It has now been found that certain groups of people are shying away from both the financial outlay and the constructive expenditure associated with hitherto known solar thermal installations for various reasons. On account of the geographical and/or structural position of the respective house, conventional solar thermal installations are not very attractive for certain house owners since the energy costs saved by using solar energy are out of proportion to the costs associated with the acquisition and mounting of a corresponding solar thermal installation.

In general, it is assumed that solar thermal installations according to the prior art must be operated for more than five years, not uncommonly for ten and more years before the energy costs saved exceed the costs incurred for the acquisition of the installation. In Germany at the time of this patent application, the usage time intervals before the so-called break-even point in corresponding model calculations are mostly between 12 and 17 years.

Although in certain countries house owners frequently live in their house for many decades, in other countries, for example, the USA, it is usual to move house frequently and sell houses after three or four years. However, conventional solar thermal installations have generally not paid themselves off within three or four years but generally do also not increase the resale value of the house by the amount of their residual value. Purchasing such a solar thermal installation is therefore not profitable for many house owners.

A particular problem with known solar thermal installations is the connection of the so-called absorber elements to the pipelines for the fluid medium. If both consist of the same material, e.g. copper, they are hitherto usually welded to one another, which however is complex and expensive. If they consist of different materials, connection is an even greater problem as a result of the different coefficients of thermal expansion which are usually present in that case.

In order to at least partially solve the last-mentioned problem, the use of so-called transfer plates has already been suggested, which plates are fastened to the absorber element in particular by adhesive bonding and hold the pipes. Since the elements are heated intensely during operation, special and expensive adhesives must be used. In addition, absorber elements and transfer plates should be made of the same material in order to have the same coefficients of thermal expansion. However, as a result of the thermal properties of the known adhesives, an adhesive layer provided between absorber element and transfer plate acts as an insulator and therefore behaves specifically counterproductively.

### DISCLOSURE OF THE INVENTION

From environmental conservation viewpoints, a greater usage of solar energy is highly desirable. It is therefore the object of the invention to provide components for a solar thermal installation which can be manufactured and mounted with low financial outlay so that a solar thermal installation constructed with these pays for itself within a very short time. At the same time, the installation should operate very efficiently and allow a high heat transfer rate between absorber element and the pipe or pipes for the fluid medium, optionally using one or a plurality of transfer plate/s. Furthermore, the installation should not only be easy to assemble but, if desired, can also be disassembled again without great expense.

It is also the object of the invention to provide a method for operating a corresponding solar thermal installation by which means particularly efficient usage of the installation is possible even under unfavourable geographical and/or structural conditions.

The object is achieved by a solar thermal installation having the features of claim 1 or claim 5, by a solar thermal installation having the features of claim 8 and by methods for operating a solar thermal installation having the features of claim 12 respectively 14. The independent claim 15 relates to a specific part of a component according to the invention.

In particular, a solar component is proposed for solar thermal installations comprising an absorber element and at least one tube for a fluid thermal medium, coupled thermally directly or indirectly to the absorber element, wherein at least one solid insulation is provided which when mounted as intended, fixes the at least one tube relative to the absorber element. This fixing can be a direct fixing, i.e. that the insulation presses the at least one tube directly against the absorber element or an indirect fixing, wherein, for example, a transfer plate is provided between insulation and tube, for example, a transfer plate having a hat-shaped cross-section. Important is the idea to use the solid insulation not as a passive component, which is adapted in shape to the structural conditions of the solar component and is solely acting as an insulation, but to use the solid insulation actively for fixing one or more tubes relative to the absorber element, especially by adhesive bonding of the absorber element to the insulation. This implicates a lot of advantages that, among others, allow to drastically reduce the production costs and to advantageously use, for example, absorber elements on which photovoltaic elements are been provided for example by thin film technology, which will is addressed in later on.

The solid insulation can, for example, consist of plastic, such as, for example, a cured plastic foam, in particular made of polyurethane or polyisocyanurate. Theoretically, the use of wood is also possible, but only if, due to the conditions at the location of use of the solar component, the solar components are not subject to such strong heating that affects the wood. Preferably however, the solid insulation consists of foam glass which has proved to be particularly suitable in regard to strength, workability and heat resistance.

One or more troughs for receiving one or more tubes and/or one or more transfer plates can be incorporated in the solid insulation. Intermediate spaces between the troughs and the tube/tubes or the transfer plate/plates can possibly be filled with heat-conducting paste.

If one or more transfer plate/plates is/are provided, the solid insulation can be foamed thereon or fastened thereon, for example, by means of clips (staples) or screws. It is also possible to use retaining profiles which pre-tension the insulation against the absorber element. Ultimately, it is important that the solid insulation allows at least one tube to be fixed relative to the absorber element without needing to use welding methods. In the embodiment currently identified as best solution, the solid insulation is just adhesively bonded to the absorber element.

A cover can be provided on the side of the solid insulation facing away from the absorber element. The absorber element can in particular comprise a flat plate which is coated with a light-absorbing paint on its side facing the sun. However, the absorber element can also comprise one or more photovoltaic element(s) which can, for example, be adhesively bonded onto an aluminum plate or be attached directly onto a corresponding plate. Such elements become very hot during operation so that they can advantageously take on the function both of a simple absorber element for solar thermal energy and also their function of power generation. At the same time, the at least one tube with the circulating medium then takes on the function of the cooling of the photovoltaic element which can advantageously increase its efficiency since the efficiency of such elements decreases from a certain temperature.

In a preferred embodiment, the solar component is configured for mounting on the roof ridge of a pitched roof. It can comprise an elongated at least partially transparent external cover, which when mounted as intended covers a part of a pipeline for fluid thermal medium. The external cover can be formed by an elongate substantially U-shaped plastic trough, but alternatively by a tensioned plastic film, in particular a polycarbonate film, wherein in the latter case a number of substantially U-shaped wire brackets are expediently then provided, wherein when mounted as intended, the wire brackets support the plastic film to form a U-shaped external cover.

The part of the pipeline for the fluid thermal medium covered by the external cover can comprise two substantially parallel tubes, in particular copper tubes, which are interconnected at one end. Advantageously, a heat-insulating wall can then be provided which when mounted as intended, divides the space enclosed by the external cover in such a manner that the two parallel tubes run on different sides of the wall. Such a wall can perform a supporting function for the external cover.

A separate retainer in particular in the form of a metal profile, in particular an aluminum profile, can be provided for the parts of the pipeline for the fluid thermal medium covered by the external cover. The retainer can preferably be configured to be at least partially light-absorbing and has at least one, preferably two elongate heating surfaces. The retainer can at least partially enclose the pipeline for the fluid thermal medium.

When mounted as intended, at least one elongate light-reflecting surface can be provided in the space enclosed by the external cover and can be disposed in such a manner that incident light is guided from said surface onto the part of the pipeline for the thermal medium covered by the external cover and/or a heating surface of the retainer. The external cover can be constructed to be double-walled.

If retaining profiles and/or a retainer are provided, this/these can be configured to be at least partially light-absorbing. In a preferred embodiment, when mounted as intended, an insulating layer is provided which thermally separates the space enclosed by the external cover from a roof, in particular a pitched roof.

In a solar thermal installation having at least one solar component according to the invention, means can advantageously be provided for changing the direction in which the fluid thermal medium flows, wherein such means can comprises a time-switching clock and/or a light sensor and/or a temperature sensor.

In a preferred embodiment, the solar thermal installation comprises a first pressureless container, in particular a tub or a bag, for the fluid thermal medium, wherein the container forms a part of a circuit for the thermal medium. A second container for fresh water or industrial water or heating water at the local water pipe pressure when mounted as intended can be disposed in the first container.

The solar thermal installation can further comprise means for extracting the heated air present in the space enclosed by a cover above the absorber element and feeding this heated air into a heating system and/or into a laundry drier.

In a method according to the invention for operating a solar thermal installation, wherein the installation is disposed on a roof or a roof ridge and comprises a pipeline for a fluid thermal medium which consists of at least two substantially parallel tubes which are interconnected at one end so that the thermal medium can flow in a first direction on the roof or roof ridge to the connection point of the two parallel tubes and can flow back in a second direction opposite thereto, it is provided that the direction of flow is reversed depending on the position of the sun so that the thermal medium always flows back in that tube which experiences strong solar irradiation.

In this method, it can advantageously be provided that the heated air present in the space enclosed by a cover above the absorber element is extracted and used to operate a heating system and/or a laundry drier.

Further details and advantages of the invention are obtained from the following purely exemplary and non-restrictive description of an exemplary embodiment in conjunction with the drawings.

### BRIEF DESCRIPTION OF THE DRAWINGS

FIG. 1 shows a highly schematic cross-section through a part of a solar thermal installation provided in one exemplary embodiment of the invention, which is configured for mounting on a roof ridge.

FIG. 2 shows highly schematically a section through a container having a clamped metal film as a tub for a plastic bladder which serves as a reservoir for a thermal medium and a container disposed in the bladder for fresh water to be heated.

FIG. 3 shows the container according to FIG. 2 in plan view but without tub and plastic bladder, to illustrate the extraction of warm air.

FIG. 4 shows schematically a section of a cross-section through a solar component provided in a further, i.e. the presently preferred, exemplary embodiment of the invention as part of a solar thermal installation which is mounted, for example, on a roof.

FIG. 5 shows schematically a section of a cross-section through a further solar component very similar to that shown in FIG. 4 which has an additional tube system for cooling a liquid.

FIG. 6 shows schematically in cross-section two solar components which are provided as parts of a solar thermal installation under a common cover and are configured similar to the solar component shown in FIG. 4 but are provided for mounting on a roof ridge.

### DESCRIPTION OF PREFERRED EMBODIMENTS

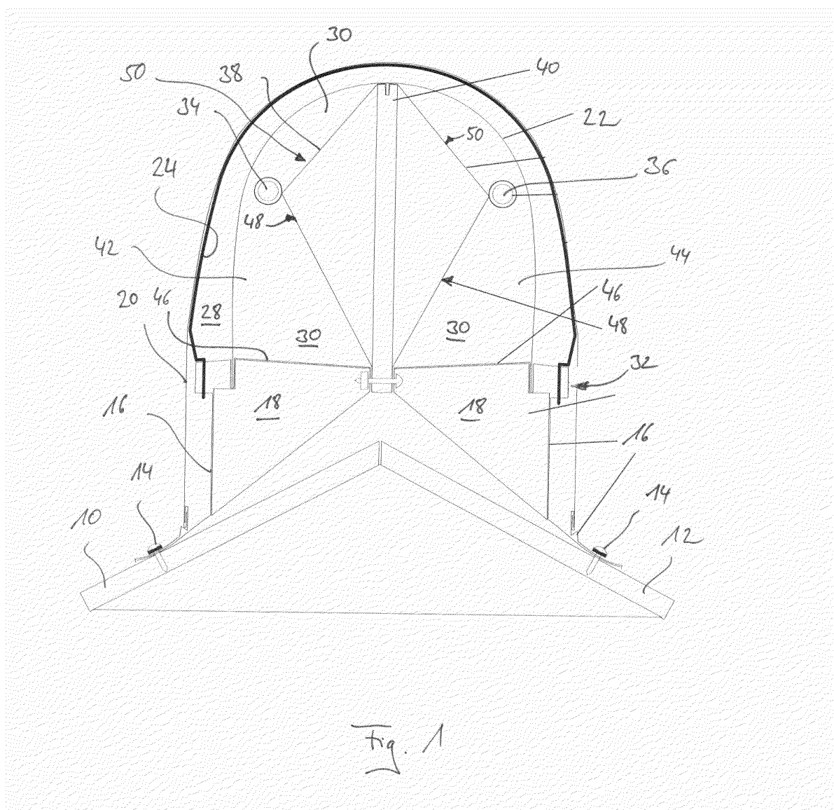

FIG. 1 shows schematically and purely as an example a cross-section through the part of a solar thermal system according to the invention which in a first exemplary embodiment is mounted on a roof, in particular in the area of the roof ridge.

In the drawing the roof ridge is indicated by the two plate-shaped elements 10 and 12. Two elongate retaining profiles 16 are fastened to these elements 10 and 12 by a plurality of fastening elements 14, e.g. in the form of nails, screws, rivets or the like, of which only two can be seen here in the section, which retaining profiles partially surround a solid thermal insulation 18 which can, for example, comprise one or two foam profiles and which serve to retain a cover constructed as double-walled in this exemplary embodiment. Depending on the configuration of the roof, the retaining profiles can also be fastened on the roof in another suitable manner for example, by adhesive bonding.

In the exemplary embodiment shown, the cover is formed by an external cover 20 and an internal cover 22 which are each at least partially transparent and preferably consist of a plastic, in particular a polycarbonate. Both the external cover 20 and also the internal cover 22 can comprise both stiff components and also films, which are clamped by means of corresponding brackets, for example, in the manner of the wire brackets 24 and are supported to form the desired shape. Semi-rigid solutions are also possible here which adopt the trough form shown in the relaxed state but which can be rolled together with a certain expenditure of force and thus can easily be transported.

If wire brackets 24 are provided, these can consist of steel. However, it is also possible to make corresponding elements of materials other than wire, in particular of a solid plastic.

The internal cover 22 and the external cover 20 enclose between them an air-filled cavity 28 which advantageously serves for the thermal insulation of the inner space 30 enclosed by the internal cover 22.

In a preferred embodiment, the retaining profiles 16 are configured to be at least partially light-absorbing, i.e. on the outer side designated by 32 so that they are heated more strongly in this region under solar irradiation. The retaining profiles which are preferably made of metal then deliver the heat to the space 28 so that the temperature difference between the inner space 30, which becomes very warm as described subsequently, and the space 28 is reduced which advantageously increases the thermal insulation effect in the sense of including the heat in the space 30.

In this exemplary embodiment two parallel tubes 34 and 36 are arranged by means of a retainer 38 in the space 30 enclosed by the internal cover 22, wherein the two tubes are interconnected at an end not shown here in such a manner that a fluid thermal medium flowing through one of the two tubes to the connection of the two tubes then flows in the opposite direction in the other of the two tubes.

In the exemplary embodiment, the retainer 38 surrounds both tubes and is otherwise configured to be substantially trapezoidal. In this exemplary embodiment, the retainer 38 comprises a single metal component. However, it is also possible to provide a separate retainer for each tube instead of a retainer holding both tubes.

The retainer 38 itself is supported by a dividing wall 40 which is made of a thermally insulating material, for example, a plastic and divides the inner space 30 into two halves 42 and 44. The inner space 30 is formed on the one hand by the inner side of the internal cover 22, on the other hand by the sections 46 of the two retaining profiles 16. In this case, the sections 46 are polished or coated with a reflecting material so that light incident through the cover is reflected by the sections 46 onto the sections 48 of the retainer 38 and the tubes 34 and 36 or since the tubes 34 and 36 are surrounded by the cover 38 in this exemplary embodiment, onto the corresponding sections of the retainer 38.

In this exemplary embodiment, the outer sides 48 and 50 of the cover 38, i.e. facing the internal cover 22, are advantageously coated with a light-absorbing paint so that the retainer is heated strongly under incident light. This heating is promoted by the sections 46 of the retaining profiles 16 being configured to be light-reflecting. The outer sides of the retainer 38 therefore experience on the one hand direct sunlight in daylight, on the other hand indirect sunlight (sunlight incident on the sections 46 of the retaining profiles 16 is reflected onto the surfaces 48 of the retainers 38, wherein when the sun is extremely low, it can also shine directly onto one of the surfaces 48).

The retainer 38 made of a good heat-conducting material delivers the heat to the tubes 34 and 36 likewise made of a heat-conducting material, in particular copper, so that a fluid thermal medium, for example, water flowing into the tubes which is at usual room temperature or outside temperature on entering into the pipelines 34 is heated.

In order to minimise the losses always present when heat is transferred, and to increase the efficiency of the solar thermal installation, in this exemplary embodiment the dividing wall 40 is provided in the inner space 30, which divides the space into two halves 42 and 44. If the sun is not exactly above the arrangement, one of the two halves always becomes warmer than the other due to the increased solar irradiation. The invention now provides to operate the solar thermal installation by means of suitable switching means so that a circulating fluid thermal medium always flows back in that half 42 or 44 of the inner space 30 which is warmer. The change of the direction of flow can be accomplished manually or automatically, for example, by means of a time switch clock and/or light sensor. The term “flow back” is understood here to means that a fluid thermal medium pumped from a reservoir not shown in FIG. 1 into one of the tubes 34 or 36 flows back again to the reservoir, in which case it is then heated compared with the exit from the reservoir and can deliver its heat to a heat exchanger known per se, wherein the release of heat can also take place directly in the reservoir, e.g. via a container for a medium to be heated, e.g. fresh water, disposed in the reservoir.

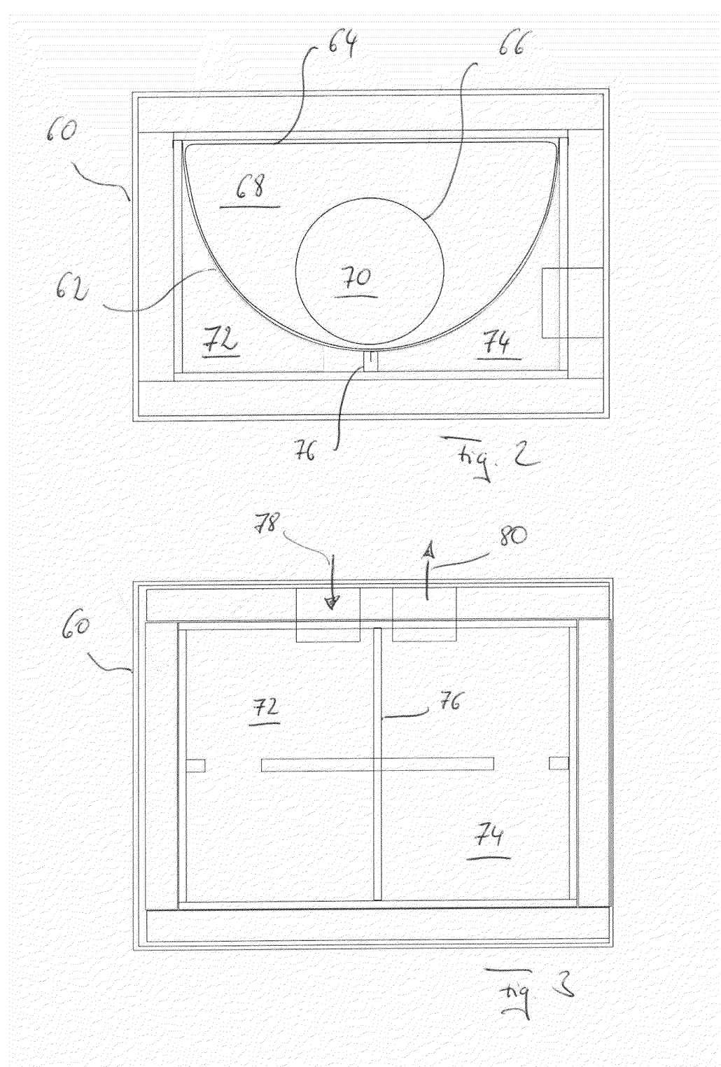

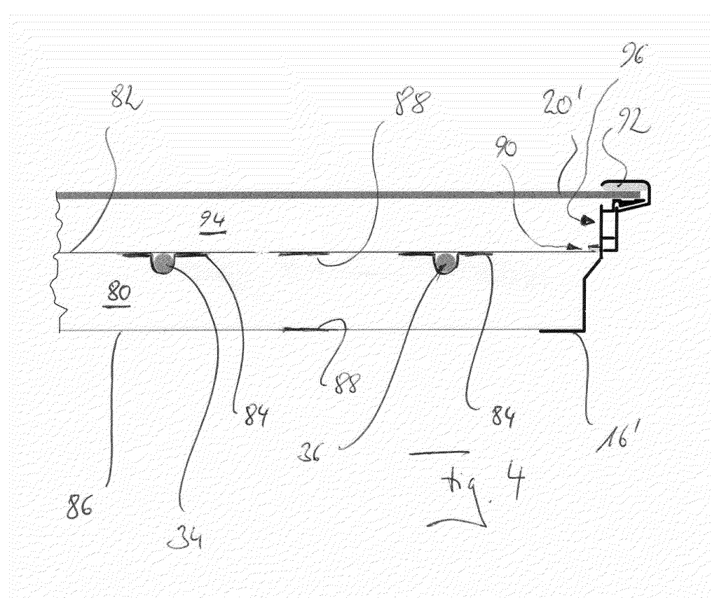

According to the invention, it is provided that the reservoir can comprise a simple container, for example in the form of a tub or a bag. Although a separate heat exchanger can be provided, a particular embodiment of the invention provides that a container for the medium to be heated, usually fresh water or industrial water, is provided in the container for the fluid thermal medium. Whilst the reservoir is set to be pressureless, the container for the medium to be heated will usually be at the pressure of the local water pipe. Typical dimensions can, for example, be: capacity of the reservoir (container) for the fluid thermal medium: 200-300 litres, capacity of the container for the medium to be heated (industrial water, fresh water): 60-70 litres. An example is shown in FIGS. 2 and 3.

FIG. 2 shows highly schematically a section through a container 60 which can advantageously comprise the container used to deliver the installation. A metal film 62 is clamped in the container, which is used to support a plastic bladder 64, the bladder being arranged around a container 66 for the medium to be heated. The bladder 64 is then filled with a thermal medium 68, for example, water but is set to be pressureless. Circulation of the thermal medium through the tubes is ensured by a pump known per se and not shown here in further detail. The medium 70 to be heated, in particular fresh water or industrial water which is usually at the pressure of the local water pipe is located in the container 66.

Cavities 72 and 74 possibly going over into one another are formed between the inner sides of the container 60 and the outer side of the film 62 facing away from the bladder 64, which in this exemplary embodiment are separated by a separating web 76 which supports the film 62 but are in air exchange with one another. During operation the air located in these cavities becomes warm. Advantageously it is now provided to use the air heated in the cavities 72 and 74 of the container 66 and specifically by providing means not shown further here for extracting the heated air and feeding this heated air into a heating system and/or a laundry drier. As indicated by the arrows 78 and 80 in FIG. 3, fresh air can be injected into the cavities and heated air extracted, in which case it is naturally provided that the cavities 72 and 74 are not hermetically separated from one another but rather are connected so that an exchange of air can take place between them in particular at a position as remote as possible from the fresh air supply and the extraction of the mentioned air.

It should also be mentioned here that air heated in the space enclosed by the cover 22 (FIG. 1) can advantageously be used by providing means for extracting the heated air and feeding this heated air into a heating system and/or into a laundry drier.

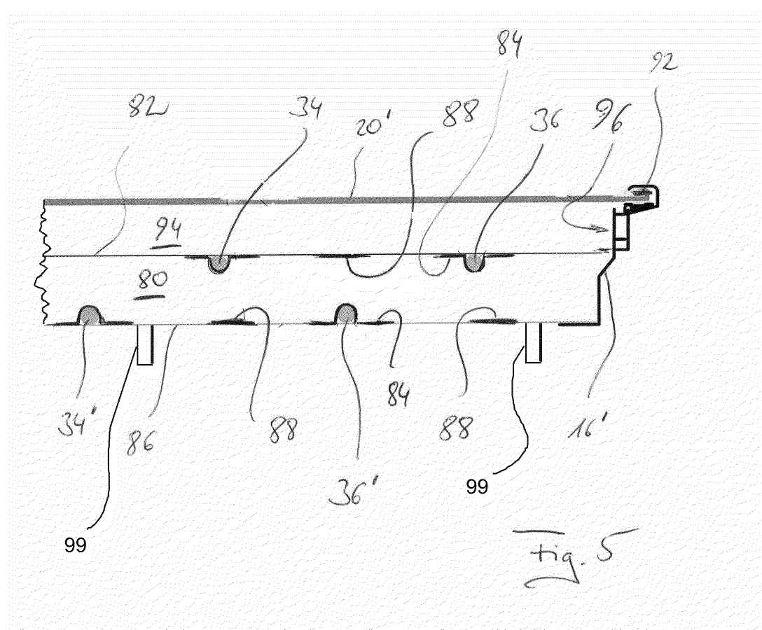

FIG. 4 shows in cross-section a section of a schematic cross-section through a component of a solar thermal installation provided in a further, i.e. presently preferred exemplary embodiment of the invention which can be mounted, for example, on a roof and which is subsequently designated as “solar component”.

The solar component can be supplied prefabricated or assembled on site and corresponds to the part shown in FIG. 1 in terms of effect. In the exemplary embodiment shown the solar component comprises a transparent cover 20′ which is held by retaining profiles 16′ of which only one is shown here, tubes of which two are shown here, i.e. the tubes 34 and 36, a solid insulation 80 consisting preferably of foam glass but which, for example, could also consist of a plastic foam, in particular polyisocyanurate or polyurethane, an absorber element 82, transfer plates 84 and, in this exemplary embodiment, a lower (provided on the lower side of the insulation 80 in the mounting state as intended) cover 86. As mentioned above, the transfer plates are optional.

The absorber element 82 and the transfer plate 84 each consist of a suitable material, in particular a metal sheet, and are disposed on the upper side of the insulation facing the cover 20′. It should be emphasised at this point that the term “sheet” was selected here according to usual linguistic usage without wishing to thereby express that this must necessarily comprise a metal part.

In the exemplary embodiment shown the absorber element is a flat sheet which is coated with a light-absorbing paint on its side facing the sun. More preferably, the absorber element can also comprise one or more photovoltaic element(s) which can, for example, be adhesively bonded to a stainless steel or aluminum plate or applied directly to a suitable support. For example, the invention allows to provide photovoltaic elements on a support plate made of, for example, stainless steel or aluminum, by thin film technology or to arrange silicon photovoltaic elements on such support plate and to use in an easy manner a such arranged support plate as an absorber element, since the tubes 34, 36 for the thermal medium do not need, thanks to the invention, to be welded to the absorber element 82 anymore, which could damage the photovoltaic elements, but could be fixed relative to the absorber element by adhesive bonding of the solid insulation with the absorber element. Depending on the design of the photovoltaic elements, they could not only be part of the absorber element but could form the absorber element.

In the exemplary embodiment shown the tubes 34 and 36 are each thermally coupled to the absorber element 82 by means of a transfer plate 84. However, these can also be thermally coupled to the absorber element without transfer plates. For example, in the case of tubes having a circular cross-section, it can be provided that heat-conducting paste is used to fill the cavities remaining between the tubes, the receptacles for the tubes incorporated in the solid insulation and the absorber element. However, the tubes can also have an angular, in particular rectangular, cross-section so that they have an outer side having a relatively large surface abutting against the absorber element.

The solid insulation 80 can be provided with a cover 86, e.g. a plastic plate, on its side facing away from the side with the absorber element 82.

The fact that absorber element and transfer plates are in direct contact without being glued or welded together also allows a particularly good heat transfer between the absorber element and the transfer plates. Since the transfer plates are adapted in terms of shape to the tubes so that a large contact surface is obtained between the transfer plates and the tubes, very good heat transfer from the absorber elements to the tubes is also ensured so that the invention works particularly efficiently. As mentioned above, the tubes can be configured so that they themselves have a relatively large surface which can come in direct contact with the absorber element; in particular, the tubes can have a rectangular cross-section.

The arrangement shown can advantageously be mounted in a particularly simple, rapid and cost-effective manner by adhesively bonding absorber element 82 and the optionally provided cover 86 at some point 88 with a suitable adhesive on the solid insulation 80 in whose recesses the tubes were inserted before. Different coefficients of thermal expansion between absorber element and solid insulation do not cause any damage since on the one hand, the bonding is not over the entire surface and on the other hand, the insulation and possibly also the adhesive is moderately elastic. A high-temperature silicone, for example, is a possible adhesive, which also has the advantage of easy processability compared with special adhesives.

The shown solar component comprises further a retaining profile 16′, which frames the absorber element 82, the upper cover 20′ and the back cover 86 on the outer sides with corresponding profile projections formed on the retaining profile 16′. In this case, a damping and sealing strip 90 can be provided between the corresponding profile projection and the absorber element 82, in the same way as such a strip 92 can also be provided between the retaining profile 16′ and the cover 20′.

The solid insulation 80 enables the absorber element 82 to come in direct contact with the transfer plates and the corresponding solar component comprising absorber, optionally provided transfer plates, solid insulation and tubes can be manufactured particularly rapidly and cost-effectively. Known solar components on the other hand usually use insulation made of materials such as rock wool which cannot provide any bearing and supporting function.

The solid insulation in the mounting state as intended can be produced in various ways, for example, as a prefabricated block of polyurethane or in particular polyisocyanurate. However, foam glass has proved to be particularly suitable. In this case, it is possible to introduce receptacles for the transfer plates and the tubes into the block directly during manufacture of such a block by using a suitable mould and also to incorporate these into the block subsequently, e.g. by milling.

However, the solid insulation can also be produced by foaming the cavity formed between the undersides of the transfer plates 84 and the absorber element 82, the upper side of the lower cover 86 and the inner sides of the retaining profiles 16′, wherein for example, it is possible to proceed by arranging spacers between cover 86 and absorber element 82 as well as between absorber element 82 and the at least partially transparent cover 20′ which then firmly clamp the parts between the retaining profiles 16′ so that the lower cavity then formed in FIG. 4 can be foamed. In this context it should be mentioned that the air located in the upper cavity 94, which is heated during operation of the installation, can be extracted as described above in connection with FIG. 1 and used for heating, for example, supplied to a laundry drier. Alternatively, the cavity shown can also be omitted entirely, particularly if photovoltaic elements take over the function of the absorber element. In this case, the photovoltaic elements are disposed above the tubes carrying the fluid medium used for the solar thermal energy and both are supported respectively fixed in their position with respect to one another by the solid insulation.

The aforementioned spacers can also ensure that firm contact and therefore good thermal coupling is obtained between the transfer plates 84 having a hat-shaped cross-section and the absorber element 82. In any case, direct abutment of the absorber element on the transfer plates is ensured.

The retaining profiles 16′ can be coated with a light-absorbing paint at least on their sections 96 facing the cavity 94, whereby the efficiency is further increased.

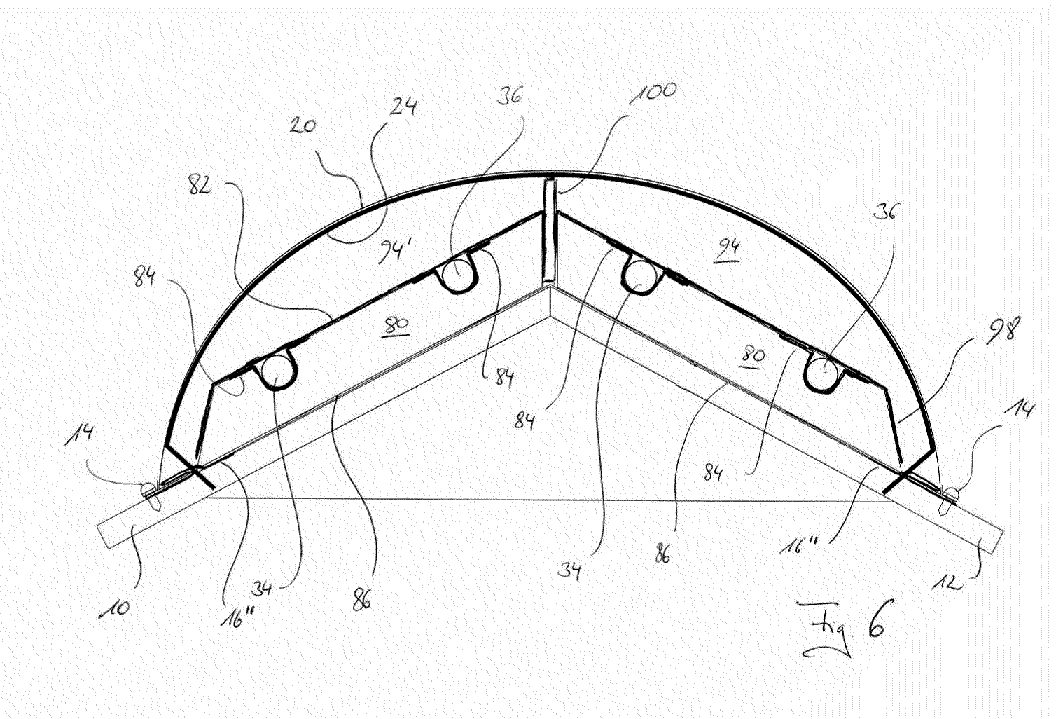

FIG. 5 shows in cross-section a section of a schematic cross-section through a component of a solar thermal installation provided in a further exemplary embodiment of the invention which can be mounted, for example, on a roof and which is subsequently designated as “solar component” like the component shown in FIG. 4.

The solar component according to FIG. 5 largely corresponds to that shown in FIG. 4 which is why the reference numbers used in FIG. 4 were used for parts having the same function as the corresponding parts in the exemplary embodiment shown in FIG. 4.

Compared with the solar component, the solar component according to FIG. 5 is mounted only schematically shown mounting elements 99 at a distance of typically about 3-6 cm above a roof and has a second system of tubes, of which two are shown here, i.e. the tubes 34′ and 36′ which are let in on the side of the solid insulation 80 facing away from the absorber element 82 and are thermally coupled to the lower cover 86 by means of transfer plates 84. The second tube system serves advantageously to circulate a warm fluid, for example, from an air-conditioning system and thereby cool this down. Thereby, a big benefit is easily achieved. For example, the solar thermal installation could be operated such that overnight a warm medium, for example water, from a tank is circulated in the second tube system to cool it down to an outer temperature of, for example, 17° C. The medium can then be used during the day instead of, for example, 35° C. warm ambient air for cooling in operating an air conditioning system.

The mounting elements 99 prevent direct contact of the solar elements with the roof, so that not an unnecessary amount of heat is dissipated via the roof to the inner of a building, which, because of the weather conditions, is probably being cooled. In addition, owing to the use of the mounting elements 99, in particular when the roof, on which the solar components are mounted, has an inclination, upon operating the second tube system to cool a medium a stack-effect can occur, so that the heated air between the roof and the solar components is quickly transported to the top and cold air can follow from the bottom, increasing the efficiency of the installation. The cooling effect can be further increased by slightly spraying in predetermined time intervals automatically or sensor controlled water on the heat dissipating side of the solar components, which then evaporates on the solar components, withdrawing heat of evaporation.

FIG. 6 shows schematically in cross-section how two solar components which are in themselves similar to the solar component shown in FIG. 4 can be configured for mounting on a roof ridge.

In this drawing the roof ridge is indicated by the two plate-shaped elements 10 and 12. Two elongate retaining profiles 16″ used to retain a cover 20 which is configured to be single-walled in this exemplary embodiment, are fastened to these elements 10 and 12 by a plurality of fastening elements 14, e.g. in the form of nails, screws, rivets or the like, of which only two can be seen in the section. As has already been mentioned in connection with FIG. 1, the retaining profiles can also be fastened to the roof in another suitable manner, for example, by adhesive bonding, depending on the configuration of the roof.

The cover 20 is at least partially transparent and preferably consists of a plastic, in particular a polycarbonate. For supporting the cover 20, wire brackets are provided along the roof ridge at intervals, similarly to that mentioned in connection with FIG. 1. In this exemplary embodiment, the cover is configured so that it comprises two solar components similarly to the solar component shown in FIG. 4. The cover 20 encloses an air-filled cavity which is divided, for example, by means of a dividing web 100 into two cavities 94 and 94′, of which one is located on the side facing the sun and therefore becomes warmer than the other. Heated air can optionally be extracted from one or both cavities as described above and supplied, for example, to a laundry drier.

The other parts shown in FIG. 6, in particular the solid insulations 80, the two absorber elements 82, the transfer plates 84 and the lower covers 86 substantially correspond to the components shown in FIG. 4, wherein these are adapted in shape to mounting in the area of the roof ridge and as a result of the common cover 20, individual covers like the cover 20′ in FIG. 4 can be omitted. In particular, the end sections 98 of the absorber elements facing away from the roof ridge can be bent so far around the respective solid insulation that light is still incident thereon even when the sun is low.

Numerous modifications and further developments are possible within the inventive idea. For example, instead of the double-walled cover shown in FIG. 1, three- and multi-walled covers or, as shown in FIG. 4, a single-walled cover can be provided. The trough-shaped cover shown in FIG. 1 can also be formed by a simple plastic tube.

The invention has many advantages. It can be produced using very simple components and can easily be retrofitted by technical laymen. For example, a kit distributed via do-it-yourself stores or by online shopping, comprising the most important parts of the solar thermal installation in a box can be provided. The aforementioned copper tubes and the elongate retaining profiles but also the possibly stiff covers, if these are not foldable in any case and the retainers can each be divided so that they can be placed on one another to form a long arrangement running, for example, over the entire roof ridge or the entire roof width but at the same time are easy to pack. The box can be designed with a bag or a film so that it can serve as a reservoir for a fluid thermal medium, usually water. A container for the medium to be heated which can be connected, for example, by means of hose or pipes into an existing water pipe system can also be supplied and possibly a pump to circulate the thermal medium. An exemplary arrangement of the solar thermal installation according to the invention could then take the form that the packing box is placed on the roof ridge and the film for the thermal medium is clamped in the box, whereupon the container for the medium to be obtained is arranged in the box and connected into an existing water pipe system by means of suitable hoses or tubes. The box is then filled with water. Hoses or pipelines with an interposed small pump lead to the tubes 34 and 36 disposed on the roof or roof ridge. When the installation is operating, thermal medium is then pumped from the base of the roof to the roof ridge in the pipes and passes through the tubes 34 and 36, wherein the direction of flow can optionally be changed depending on the position of the sun as has already been described above. The thermal medium in the reservoir is heated and delivers some of its heat to the fresh water or industrial water located in the container for the medium to be heated.

The installation is easy to mount and dismount. It can be manufactured and supplied extremely cost-effectively. Regardless of whether the roof has large surfaces facing the sun, the installation can nevertheless be operated economically as a result of its configuration provided that the roof has one section exposed to the sun. The cost-effective manufacturability and deliverability of the installation has the result that a purchase is worthwhile even for those home owners who already know that they would wish to sell their house again after a few years. When selling a house fitted with such a installation if the buyer is not prepared to pay a corresponding extra price for the house, the installation can easily be dismounted and taken away by the seller of the house. The installation therefore substantially increases the incentive to use renewable energy, here in the form of solar energy, and therefore contributes to protecting the environment.

What is claimed is:

1. A solar component for solar thermal installations comprising an absorber element and at least one tube for a fluid thermal medium, coupled thermally directly or indirectly to the absorber element,
wherein at least one solid insulation preferably of foam glass or plastic, in particular a cured plastic foam, in particular of polyurethane or polyisocyanurate, is provided which when mounted as intended, fixes the at least one tube relative to the absorber element.

2. The solar component according to claim 1, wherein said absorber element is adhesively bonded to said solid insulation.

3. The solar component according to claim 1, comprising at least one transfer plate for receiving and thermal coupling of the at least one tube to the absorber element.

4. The solar component according to claim 1, comprising, on the side of the at least one solid insulation facing away from the absorber element, at least one tube for a fluid thermal medium to be cooled.

5. The solar component according to claim 1, configured for mounting on the roof ridge of a pitched roof.

6. The solar component according to claim 1, comprising an elongate at least partially transparent external cover, in particular in the form of an elongate substantially U-shaped plastic trough, which when mounted as intended, covers a part of a pipeline for fluid thermal medium.

7. The solar component according to claim 1, comprising a photovoltaic element, in particular a photovoltaic element that forms part of the absorber element or the entire absorber element.

8. A solar thermal installation comprising at least one solar component according to claim 1.

9. The solar thermal installation according to claim 8, comprising means for changing the direction in which the fluid thermal medium flows, wherein the said means preferably comprises a time-switching clock and/or a light sensor and/or a temperature sensor.

10. The solar thermal installation according to claim 8, comprising a pressureless first container, in particular a tub or a bag, for the fluid thermal medium, wherein the first container forms a part of a circuit for the thermal medium, wherein a second container for fresh water or industrial water or heating water at the local water pipe pressure when mounted as intended is preferably disposed in the first container.

11. The solar thermal installation according to claim 8, comprising means for extracting the heated air present in the space enclosed by a cover above the absorber element and feeding this heated air into a heating system and/or into a laundry drier.

12. A method for operating a solar thermal installation according to claim 8, wherein the installation is disposed on a roof or a roof ridge and comprises a pipeline for a fluid thermal medium which consists of at least two substantially parallel tubes which are interconnected at one end so that the thermal medium can flow in a first direction on the roof or roof ridge to the connection point of the two parallel tubes and can flow back in a second direction opposite thereto, comprising the step of reversing the direction of flow depending on the position of the sun so that the thermal medium always flows back in that tube which experiences strong solar irradiation.

13. The method according to claim 12, wherein the heated air present in the space enclosed by a cover above the absorber element is extracted and used to operate a heating system and/or a laundry drier.

14. A method for operating a solar thermal installation, said installation comprising solar components according to claim 4, the method comprising the step of piping a fluid thermal medium to be cooled through at least one tube provided on the side of the at least one solid insulation facing away from the absorber element.

15. A solid insulation for a solar component for solar thermal installations comprising an absorber element and at least one tube for a fluid thermal medium thermally coupled directly or indirectly to the absorber element, wherein said solid insulation consists of foam glass or plastic, in particular a cured plastic foam, in particular made of polyurethane or polyisocyanurate,
wherein the solid insulation is configured in such a manner that when mounted as intended it fixes the at least one tube relative to the absorber element.
